(19) United States
(12) Patent Application Publication
(10) Pub. No.: US 2025/0071985 A1
(43) Pub. Date: Feb. 27, 2025

(54) SEMICONDUCTOR DEVICE WITH RESISTANCE MODIFICATION DOPED REGION

(71) Applicant: NANYA TECHNOLOGY CORPORATION, NEW TAIPEI CITY (TW)

(72) Inventor: WEI-ZHONG LI, TAOYUAN CITY (TW)

(21) Appl. No.: 18/511,029

(22) Filed: Nov. 16, 2023

Related U.S. Application Data
(62) Division of application No. 18/238,022, filed on Aug. 25, 2023.

(51) Int. Cl. H10B 20/25

(52) U.S. Cl. CPC H10B 20/25

(57) ABSTRACT

A semiconductor device and method of manufacturing the same are provided. The semiconductor device includes a substrate, a well region, a fuse medium, a gate electrode, a fuse doped region, a source/drain (S/D) region, and a resistance modification doped region. The well region is within the substrate with a first conductive type. The fuse medium is disposed over the substrate. The gate electrode is disposed over the fuse medium. The fuse doped region is under the gate electrode with a second conductive type different from first conductive type. The S/D region is adjacent to the fuse doped region with the second conductive type. The resistance modification doped region has the second conductive type and partially overlaps the fuse doped region.

### CROSS-REFERENCE TO RELATED APPLICATION

This application is a divisional application of U.S. Non-Provisional application Ser. No. 18/238,022 filed Aug. 25, 2023, which is incorporated herein by reference in its entirety.

### TECHNICAL FIELD

The present disclosure relates to a semiconductor device, and in particularly to a semiconductor device with a resistance modification doped region.

### DISCUSSION OF THE BACKGROUND

With the rapid growth of the electronics industry, the development of integrated circuits (ICs) has achieved high performance and miniaturization. Technological advances in IC materials and design have produced generations of ICs where each generation has smaller and more complex circuits than the previous generation.

A Dynamic Random Access Memory (DRAM) device is a type of random access memory that stores each bit of data in a separate capacitor within an integrated circuit. Typically, a DRAM is arranged in a square array of one capacitor and transistor per cell. A vertical transistor has been developed for the 4F² DRAM cell, in which F represents the photolithographic minimum feature width or critical dimension (CD). However, recently, DRAM manufacturers are facing significant challenges as technology nodes improve.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a well region, a fuse medium, a gate electrode, a fuse doped region, a source/drain (S/D) region, and a resistance modification doped region. The well region is within the substrate with a first conductive type. The fuse medium is disposed over the substrate. The gate electrode is disposed over the fuse medium. The fuse doped region is under the gate electrode with a second conductive type different from first conductive type. The S/D region is adjacent to the fuse doped region with the second conductive type. The resistance modification doped region has the second conductive type and partially overlaps the fuse doped region.

One aspect of the present disclosure provides a semiconductor a fuse medium, a gate electrode, a fuse doped region, a source/drain (S/D) region, and nitrogen derivative impurities. The well region is within the substrate with a first conductive type. The fuse medium is disposed over the substrate. The gate electrode is disposed over the fuse medium. The fuse doped region is under the gate electrode with a second conductive type different from first conductive type. The S/D region is adjacent to the fuse doped region with the second conductive type. The nitrogen derivative impurities are within the substrate and under the gate electrode.

Another aspect of the present disclosure provides a method of manufacturing a semiconductor device. The method includes: providing a substrate, wherein a well region is within the substrate with a first conductive type; forming a resistance modification doped region within the substrate, wherein the resistance modification doped region has a second conductive type different from the first conductive type; forming a fuse doped region within the substrate, wherein the fuse doped region has the second conductive type; and forming a gate electrode over the fuse doped region.

The embodiments of the present disclosure provide a semiconductor device. The semiconductor device may include a resistance modification doped region. The resistance modification doped region may make a fuse to be an ohmic type fuse when a fuse medium is blown out under an operation current under 4 mA (e.g., a current under 1.2 mA). The resistance of an ohmic type fuse is positively proportional to a temperature and has a resistance with a lower deviation. As a result, the misjudgment of the determination of a read operation and/or a write operation can be reduced.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

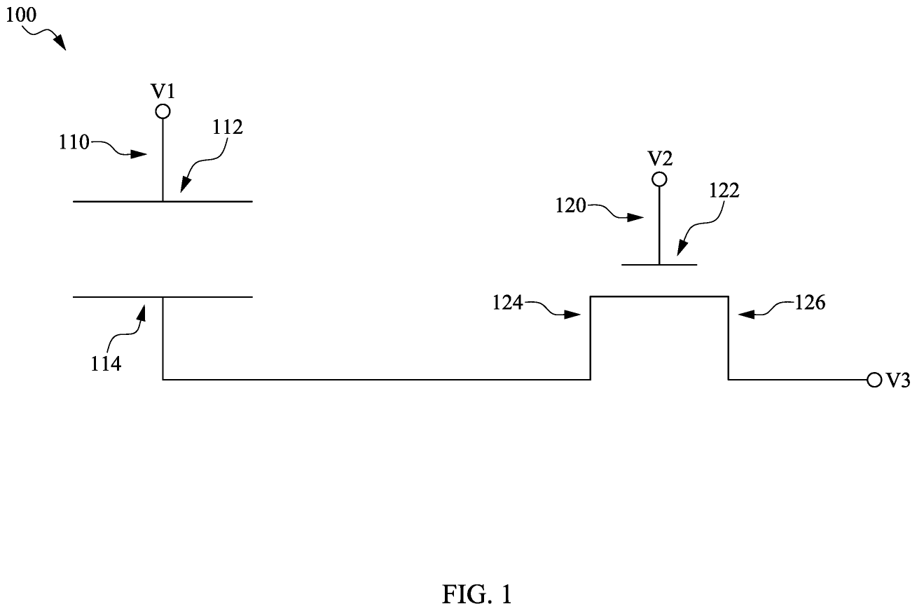

FIG. 1 is a diagram of a circuit in accordance with some embodiments of the present disclosure.

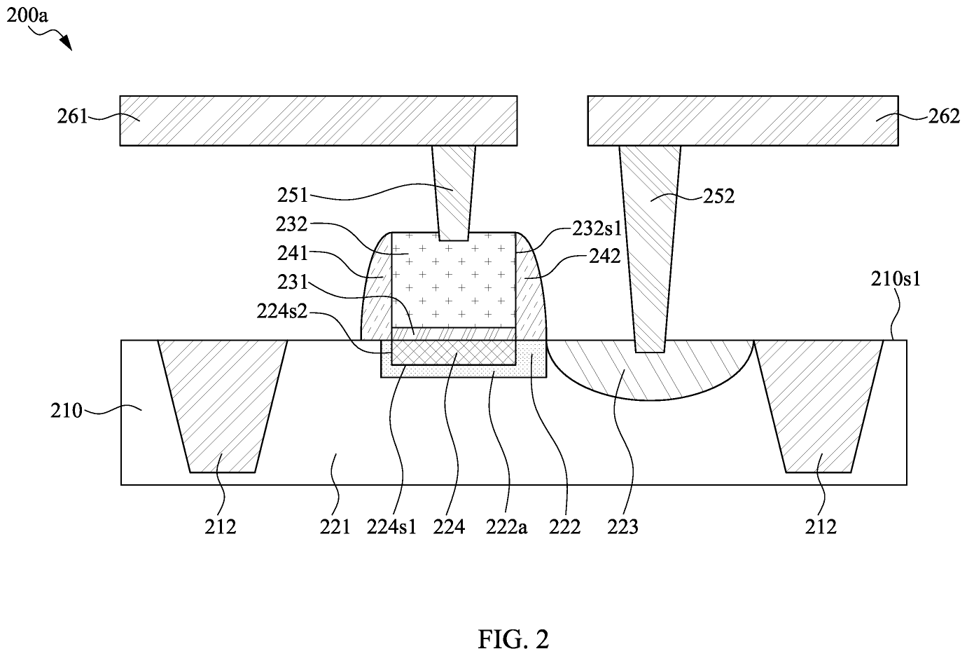

FIG. 2 is a cross-section of a semiconductor device, in accordance with some embodiments of the present disclosure.

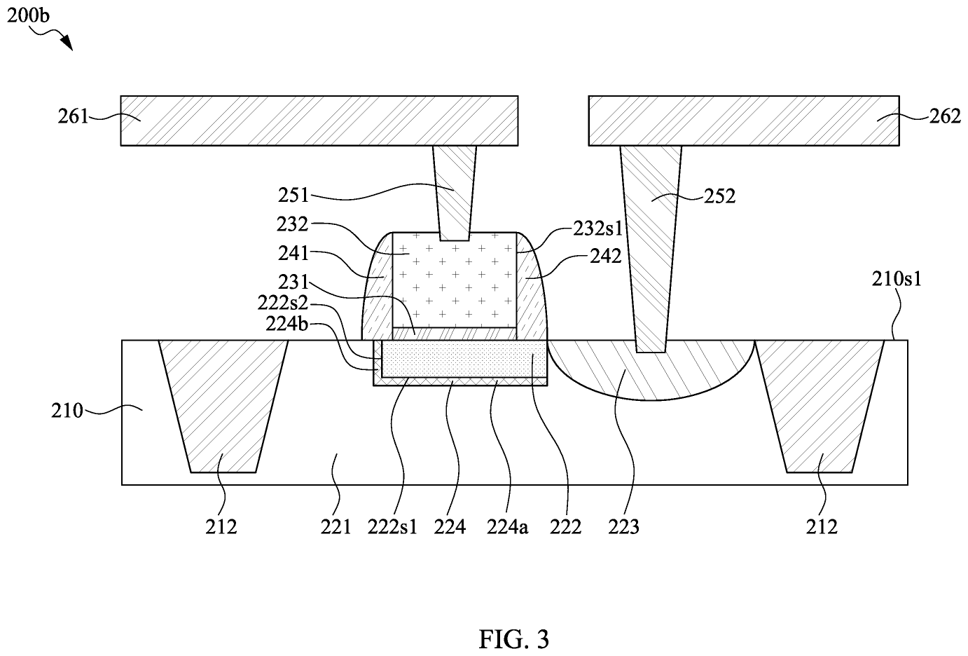

FIG. 3 is a cross-section of a semiconductor device, in accordance with some embodiments of the present disclosure.

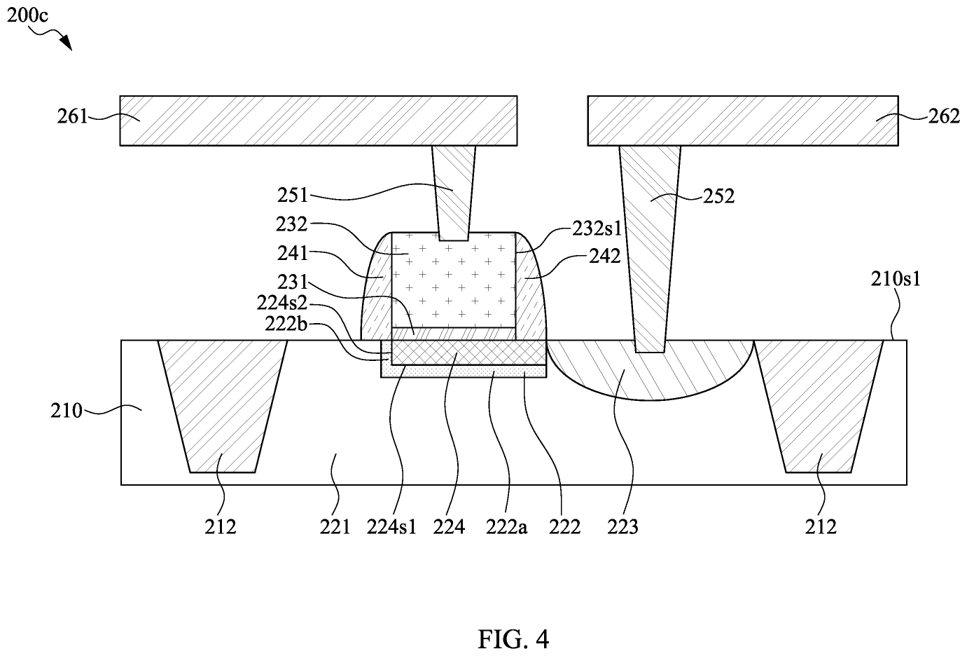

FIG. 4 is a cross-section of a semiconductor device, in accordance with some embodiments of the present disclosure.

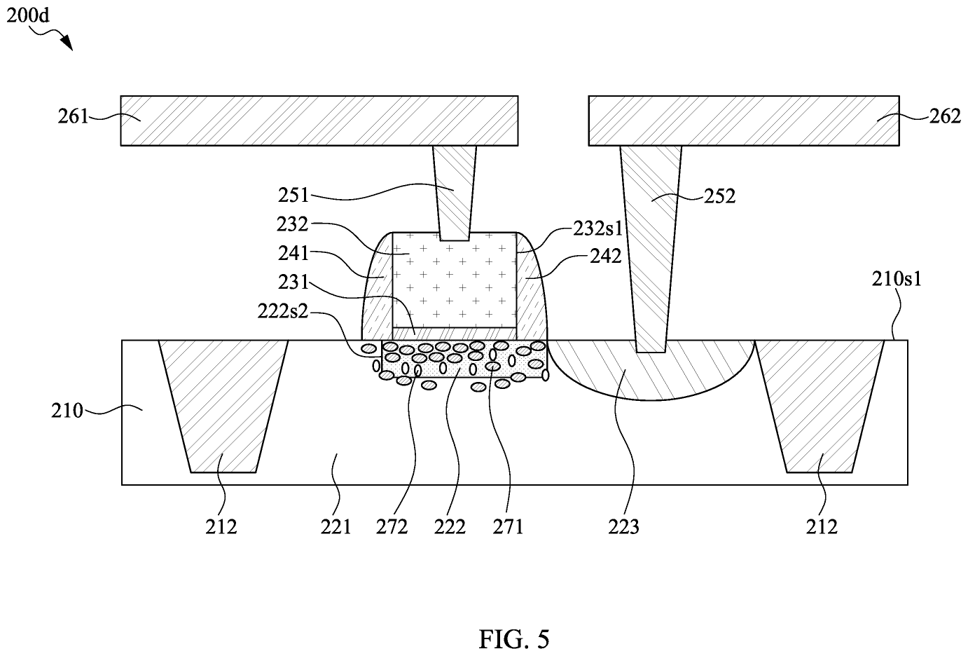

FIG. 5 is a cross-section of a semiconductor device, in accordance with some embodiments of the present disclosure.

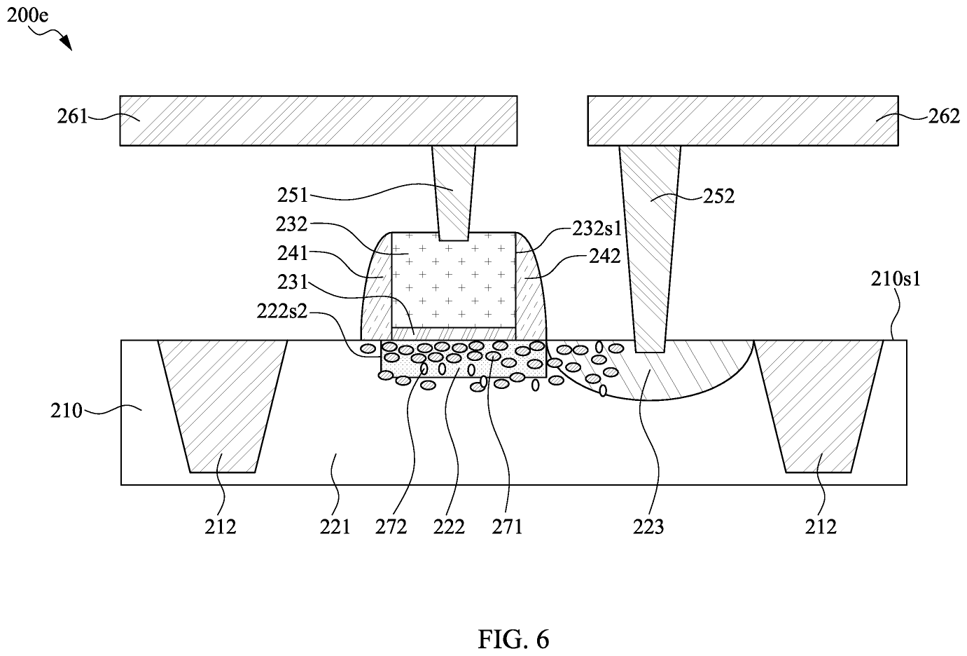

FIG. 6 is a cross-section of a semiconductor device, in accordance with some embodiments of the present disclosure.

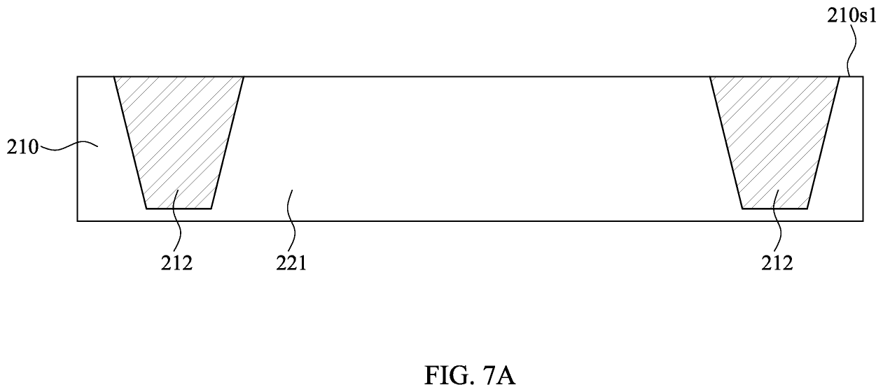

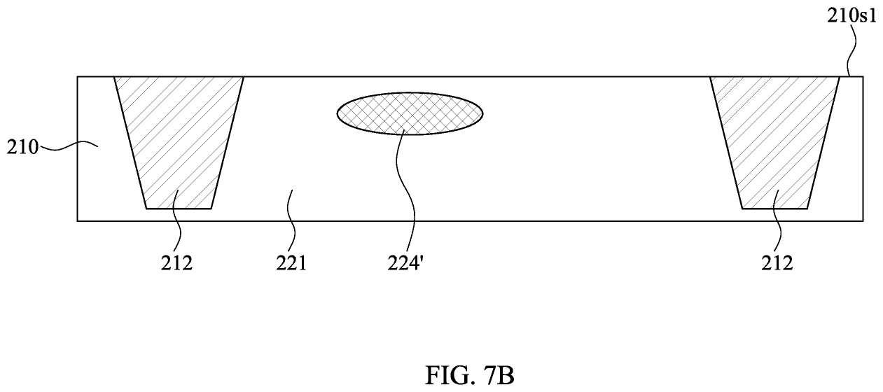

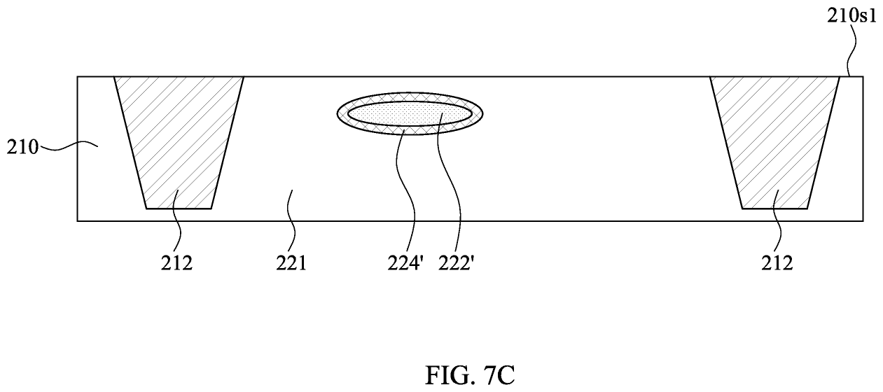

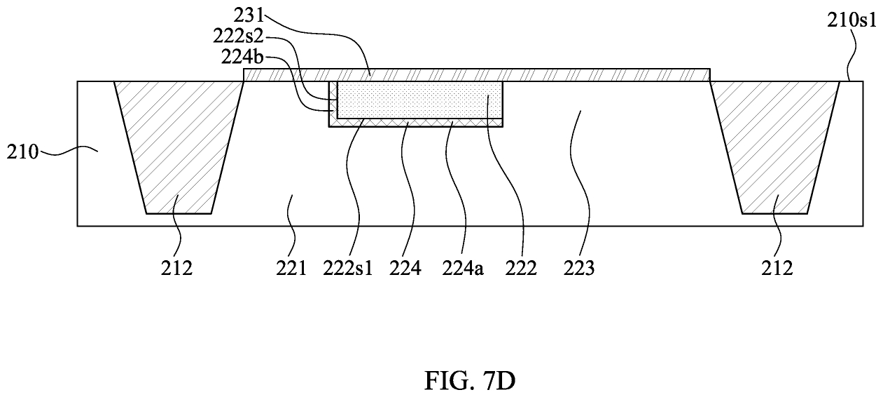

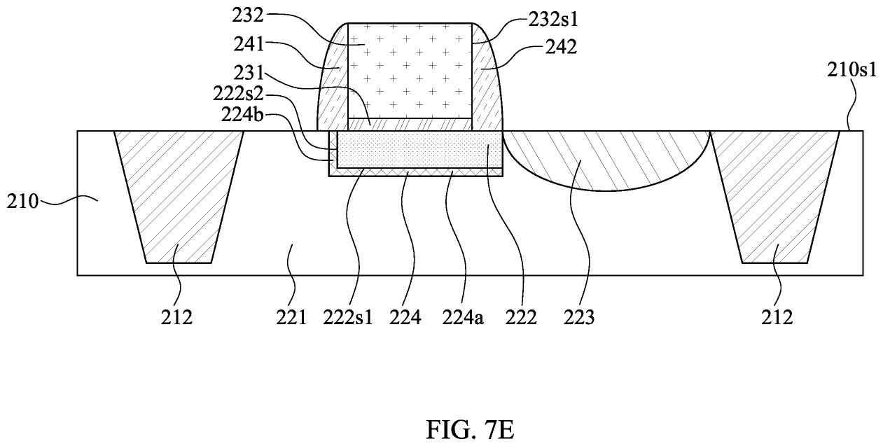

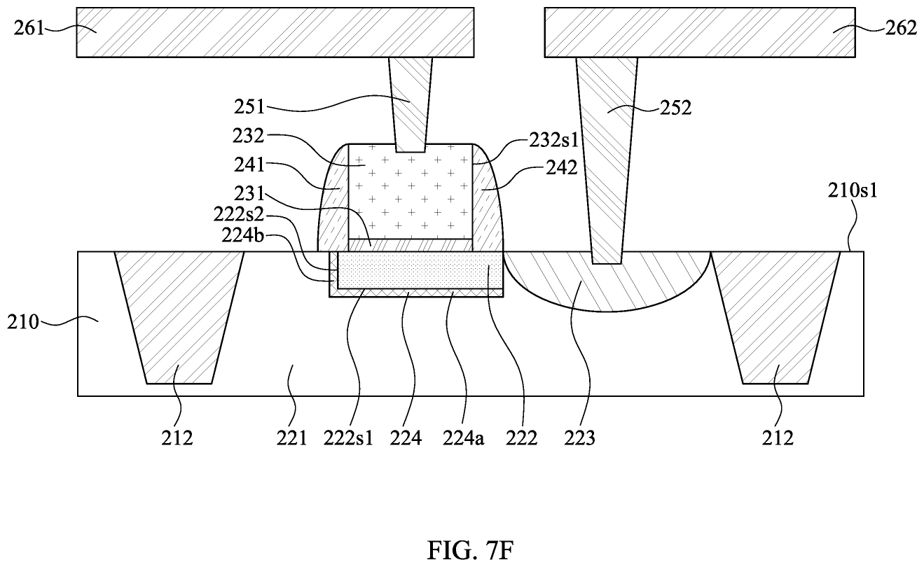

FIG. 7A illustrates one or more stages of an exemplary method for manufacturing a semiconductor device according to some embodiments of the present disclosure.

FIG. 7B illustrates one or more stages of an exemplary method for manufacturing a semiconductor device according to some embodiments of the present disclosure.

FIG. 7C illustrates one or more stages of an exemplary method for manufacturing a semiconductor device according to some embodiments of the present disclosure.

FIG. 7D illustrates one or more stages of an exemplary method for manufacturing a semiconductor device according to some embodiments of the present disclosure.

FIG. 7E illustrates one or more stages of an exemplary method for manufacturing a semiconductor device according to some embodiments of the present disclosure.

FIG. 7F illustrates one or more stages of an exemplary method for manufacturing a semiconductor device according to some embodiments of the present disclosure.

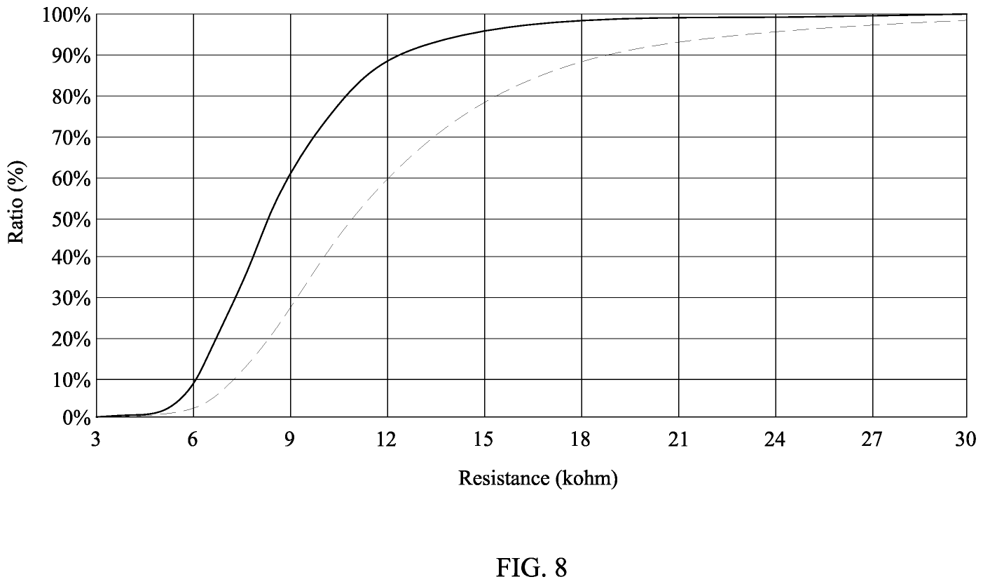

FIG. 8 illustrates a diagram showing a relation between a temperature and a resistance of a hopping type fuse.

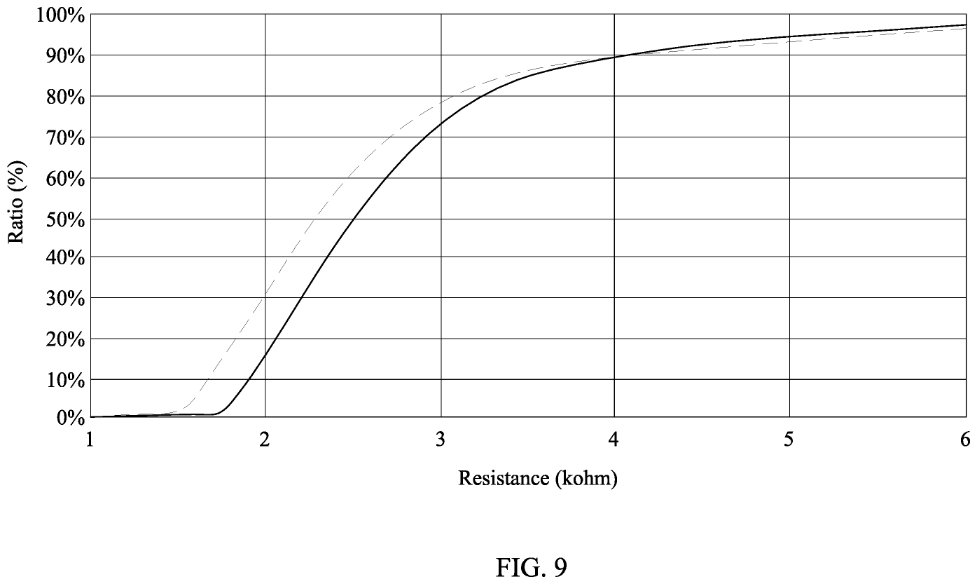

FIG. 9 illustrates a diagram showing a relation between a temperature and a resistance of an ohmic type fuse.

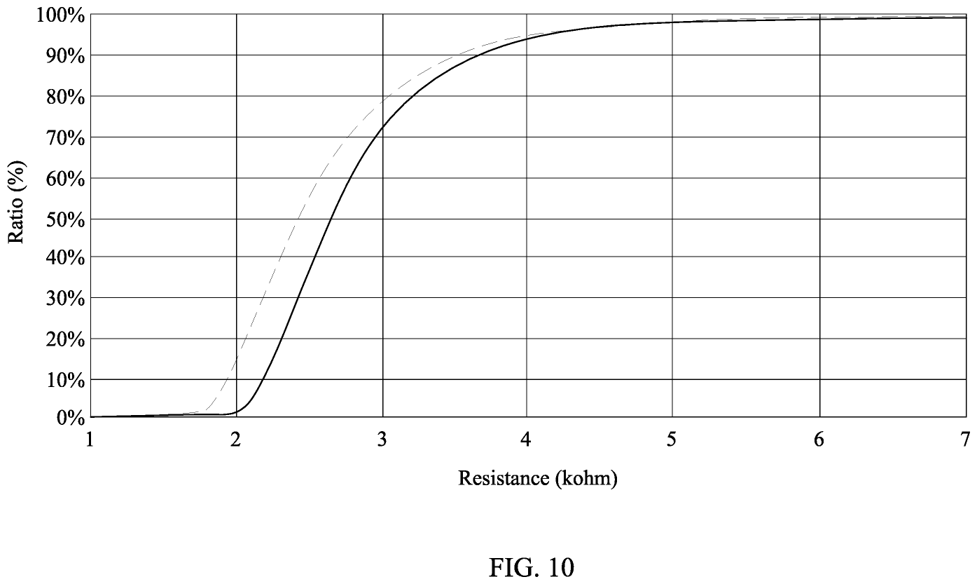

FIG. 10 illustrates a diagram showing a relation between a temperature and a resistance of an ohmic type fuse.

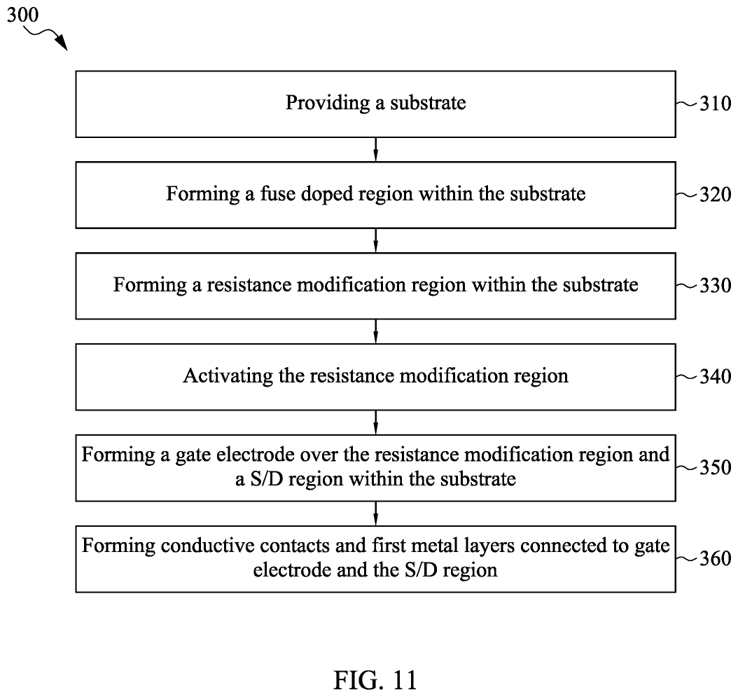

FIG. 11 is a flowchart illustrating a method of manufacturing a semiconductor device, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that when an element is referred to as being “connected to” or “coupled to” another element, the initial element may be directly connected to, or coupled to, another element, or to other intervening elements.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure employed refers to variation in the numerical quantity that may occur, for example, through typical measuring and liquid handling procedures used for making concentrates or solutions. Furthermore, variation may occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

FIG. 1 is a diagram of a circuit 100 in accordance with some embodiments of the present disclosure. In some embodiments, the circuit 100 may include a fuse 110 and a transistor 120. The circuit 100 may be included in a memory device, such as a dynamic random access memory (DRAM) device, a one-time programming (OTP) memory device, a static random access memory (SRAM) device, or other suitable memory devices.

The fuse 110 may include a terminal 112 and a terminal 114. The terminal 112 may be electrically connected to a supply voltage V1. The terminal 114 may be electrically connected to the transistor 120.

The transistor 120 may be electrically connected to the fuse 110. The transistor 120 may include a terminal 122, a terminal 124, and a terminal 126. The terminal 122 may be electrically connected to a supply voltage V2. The terminal 124 may be electrically connected to the terminal 114. The terminal 126 may be electrically connected to a supply voltage V3.

In some embodiments, during a read operation, a word line (e.g., the terminal 122) may be asserted, turning on the transistor 120. The enabled transistor 120 allows the voltage across the fuse 110 to be read by a detection amplifier through a bit line (not shown). During a write operation, the data to be written may be provided on the bit line when the word line is asserted.

FIG. 2 is a cross-section of a semiconductor device 200a, in accordance with some embodiments of the present disclosure. In some embodiments, the semiconductor device 200a may be applicable to the circuit 100. More specifically, the semiconductor device 200a may include a structure that functions as a fuse, such as the fuse 110 as shown in FIG. 1.

In some embodiments, the semiconductor device 200a may include a substrate 210. The substrate 210 may be a semiconductor substrate, such as a bulk semiconductor, a semiconductor-on-insulator (SOI) substrate, or the like. The substrate 210 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may include a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 210 may have a multilayer structure, or the substrate 210 may include a multilayer compound semiconductor structure. The substrate 210 may have a surface 210s1.

The semiconductor device 200a may include an isolation region 212. The isolation region 212 may be recessed from the surface 210s1. In some embodiments, the isolation region 212 may be a shallow trench isolation (STI). In other embodiments, the isolation region 212 may include a structure of a local oxidization of silicon (LOCOS) structure, or any other suitable isolation structure. The isolation region 212 may include a dielectric material, such as oxide, nitride, or other suitable materials.

In some embodiments, the semiconductor device 200a may include a well region 221. The well region 221 may be disposed within the substrate 210. The well region 221 may have a first conductive type. In some embodiments, the first conductive type is a p type. In some embodiments, p type dopants include boron (B), other group III elements, or any combination thereof.

In some embodiments, the semiconductor device 200a may include a fuse doped region 222. The fuse doped region 222 may be disposed within the substrate 210. The fuse doped region 222 may have a second conductive type different from the first conductive type. In some embodiments, the second conductive type is an n type. In some embodiments, n type dopants include arsenic (As), phosphorus (P), antimony (Sb), other group V elements, or any combination thereof.

In some embodiments, the semiconductor device 200a may include a source/drain (S/D) region 223. The S/D region 223 may be disposed within the substrate 210. The S/D region 223 may be adjacent to the fuse doped region 222. The S/D region 223 may be in contact with the fuse doped region 222. The S/D region 223 may partially overlap the fuse doped region 222. The S/D region 223 may have the second conductive type. In some embodiments, the S/D region 223 may have dopants including arsenic, phosphorus, other group V elements, or any combination thereof.

In some embodiments, the semiconductor device 200a may include a resistance modification doped region 224. The resistance modification doped region 224 may be disposed within the substrate 210. The resistance modification doped region 224 may overlap the fuse doped region 222. The resistance modification doped region 224 may have the second conductive type. In some embodiments, the resistance modification doped region 224 may have dopants including nitrogen (N) and/or nitrogen derivatives. In some embodiments, the dopant concentration of the resistance modification doped region 224 may range from about 10¹⁵ cm⁻³ to about 10¹⁶ cm⁻³.

In some embodiments, the resistance modification doped region 224 may be configured to make the semiconductor device 200a as an ohmic type fuse after the semiconductor device 200a is blown out, which will be described in detail later. In some embodiments, the resistance modification doped region 224 may be configured to modify the relation between the resistance of a fuse (e.g., the semiconductor device 200a) and a temperature under a specific operation current. For example, the resistance modification doped region 224 may make the resistance of a fuse (e.g., the semiconductor device 200a) positively proportional to a temperature under an operation current ranging from about 0.4 mA to about 1.2 mA, such as 0.4 mA, 0.5 mA, 0.6 mA, 0.7 mA, 0.8 mA, 0.9 mA, 1 mA, 1.1 mA, or 1.2 mA. The operation current may be configured to blow a fuse medium (e.g., fuse medium 231) out, and therefore a resistance of a fuse medium may be changed.

In some embodiments, the semiconductor device 200a may include a fuse medium 231. The fuse medium 231 may be disposed on the surface 210s1 of the substrate 210. In some embodiments, the fuse medium 231 may vertically overlap the fuse doped region 222. In some embodiments, the fuse medium 231 may vertically overlap the resistance modification doped region 224. The fuse medium 231 may have a single layer or a multi-layer structure. In some embodiments, the fuse medium 231 may include dielectric material such as silicon oxide, silicon nitride, silicon oxynitride, other dielectric materials, or a combination thereof. In some embodiments, the fuse medium 231 is a multi-layer structure that includes an interfacial layer and a high-k (dielectric constant greater than 4) dielectric layer. The interfacial layer can include dielectric material such as silicon oxide, silicon nitride, silicon oxynitride, other dielectric materials, or a combination thereof. The high-k dielectric layer can include high-k dielectric material such as HfO₂, HfSiO, HfSiON, HfTaO, HfTiO, HfZrO, other suitable high-k dielectric materials, or a combination thereof. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

In some embodiments, the semiconductor device 200a may include a gate electrode 232. The gate electrode 232 may be disposed on the fuse medium 231. The gate electrode 232 may include polysilicon, silicon-germanium, and/or at least one metallic material including elements and compounds such as Mo, Cu, W, Ti, Ta, TiN, TaN, NiSi, CoSi, or other suitable conductive materials known in the art. In some embodiments, the gate electrode 232 includes a work function metal layer that provides a metal gate with an n-type-metal work function or p-type-metal work function. The p-type-metal work function materials include materials such as ruthenium, palladium, platinum, cobalt, nickel, conductive metal oxide, or other suitable materials. The n-type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials.

In some embodiments, the semiconductor device 200a may include a spacer 241 and a spacer 242. The spacer 241 may be disposed on a lateral surface 232s1 of the gate electrode 232. The spacer 242 may be disposed on the lateral surface 232s1 of the gate electrode 232. The spacer 241 and spacer 242 may include a single layer structure or a multilayer structure. The spacer 241 and spacer 242 may include dielectric material such as silicon oxide, silicon nitride, silicon oxynitride, other dielectric materials, or a combination thereof. In some embodiments, the spacer 241 (or spacer 242) may vertically overlap the fuse doped region 222. In some embodiments, the spacer 241 (or spacer 242) may be free from vertically overlapping the resistance modification doped region 224.

In some embodiments, the semiconductor device 200a may include a conductive contact 251 and a conductive contact 252. The conductive contact 251 may be disposed on the gate electrode 232. The conductive contact 251 may be electrically connected to the gate electrode 232. The conductive contact 252 may be disposed on the S/D region 223. The conductive contact 252 may be electrically connected to the S/D region 223. The conductive contact 251 and the conductive contact 252 may include a conductive material. The conductive material may include tungsten, copper, aluminum, tantalum, or other suitable materials.

In some embodiments, the semiconductor device 200a may include a metal layer 261 and a metal layer 262. The metal layer 261 may be disposed on the conductive contact 251. The metal layer 261 may be electrically connected to the conductive contact 251. The metal layer 262 may be disposed on the conductive contact 252. The metal layer 262 may be electrically connected to the conductive contact 252. The metal layer 261 and the metal layer 262 may include a conductive material. The conductive material may include tungsten, copper, aluminum, tantalum, or other suitable materials.

In this embodiment, the dimension (e.g., area or volume) of the fuse doped region 222 may be greater than that of the resistance modification doped region 224. In some embodiments, the fuse doped region 222 may have a portion 222a disposed under or below a lower boundary 224s1 of the resistance modification doped region 224. In some embodiments, the fuse doped region 222 may exceed a lateral boundary 224s2 of the resistance modification doped region 224.

In a comparative semiconductor device, when the fuse medium is blown out under an operation current less than 4 mA, the resistance of the blown fuse is negatively proportional to a temperature, and such fuse (or blown fuse) may be referred to as a hopping type fuse. The hopping type fuse has a resistance with a higher deviation, which may cause a misjudgment of the determination of a read operation and/or a write operation. In this embodiment, the resistance modification doped region 224 may make the fuse medium 231 to be an ohmic type fuse when the fuse medium 231 is blown out under an operation current less than 4 mA (e.g., a current less than 1.2 mA). The resistance of an ohmic type fuse is positively proportional to a temperature, and has a lower deviation. As a result, the misjudgment of the determination of a read operation and/or a write operation can be reduced.

FIG. 3 is a cross-section of a semiconductor device 200b, in accordance with some embodiments of the present disclosure. The semiconductor device 200b is similar to the semiconductor device 200a as shown in FIG. 2, with differences therebetween as follows.

In some embodiments, the dimension (e.g., area or volume) of the fuse doped region 222 may be less than that of the resistance modification doped region 224. In some embodiments, the resistance modification doped region 224 may have a portion 224a disposed under or below a lower boundary 222s1 of the fuse doped region 222. In some embodiments, the resistance modification doped region 224 may exceed a lateral boundary 222s2 of the fuse doped region 222. In some embodiments, the resistance modification doped region has a portion 224b which may be disposed between the fuse doped region 222 and the substrate 210. In some embodiments, the spacer 241 may vertically overlap the resistance modification doped region 224. In some embodiments, the spacer 242 may vertically overlap the resistance modification doped region 224. In some embodiments, the resistance modification doped region 224 may be in contact with the S/D region 223. In some embodiments, the resistance modification doped region 224 may partially overlap the S/D region 223.

FIG. 4 is a cross-section of a semiconductor device 220c, in accordance with some embodiments of the present disclosure. The semiconductor device 200c is similar to the semiconductor device 200a as shown in FIG. 2, with differences therebetween as follows.

In some embodiments, the fuse doped region 222 may have a portion 222b exceeding the lateral boundary 224s2 of the resistance modification doped region 224. In some embodiments, the spacer 241 may be free from vertically overlapping the resistance modification doped region 224, and the spacer 242 may vertically overlap the resistance modification doped region 224.

FIG. 5 is a cross-section of a semiconductor device 200d, in accordance with some embodiments of the present disclosure. The semiconductor device 200d is similar to the semiconductor device 200a as shown in FIG. 2, with differences therebetween as follows.

In some embodiments, the semiconductor device 200d may include impurities 271 and impurities 272. In some embodiments, the impurity 271 may be doped within the substrate 210. In some embodiments, the impurity 271 may be doped under the gate electrode 232. In some embodiments, the impurity 271 may be doped within the fuse doped region 222. The impurity 271 may include nitrogen derivative impurities. In some embodiments, the impurity 271 may include nitride. In some embodiments, the impurity 271 may include oxynitride. In some embodiments, a portion of the impurity 271 may be located beyond or outside the fuse doped region 222. In some embodiments, the impurity 271 may located under the spacer 241. In some embodiments, the impurity 271 may located under the spacer 242. In some embodiments, the concentration of the impurity 271 may be gradient or uneven. For example, the impurity 271 may have a higher concentration near the surface 210s1 and a lower concentration below the fuse doped region 222.

In some embodiments, the impurity 272 may be doped within the substrate 210. In some embodiments, the impurity 272 may be doped under the gate electrode 232. In some embodiments, the impurity 272 may be doped within the fuse doped region 222. The impurity 272 may include nitrogen.

The impurity 271 and/or 272 may modify the resistance of the fuse and make the fuse medium 231 to be an ohmic type fuse when the fuse medium 231 is blown out under an operation current under 4 mA (e.g., a current under 1.2 mA). As a result, the misjudgment of the determination of a read operation and/or a write operation can be reduced.

FIG. 6 is a cross-section of a semiconductor device 200e, in accordance with some embodiments of the present disclosure. The semiconductor device 200e is similar to the semiconductor device 200d as shown in FIG. 5, with differences therebetween as follows.

In some embodiments, the impurity 271 may be located within the S/D region 223. In some embodiments, the impurity 272 may be located within the S/D region 223.

FIG. 7A, FIG. 7B, FIG. 7C, FIG. 7D, FIG. 7E, and FIG. 7F illustrates one or more stages of an exemplary method for manufacturing a semiconductor device according to some embodiments of the present disclosure.

Referring to FIG. 7A, a substrate 210 may be provided. An isolation region 212 may be formed within the substrate 210 to define a region of a fuse.

Referring to FIG. 7B, a doped region 224′ may be doped into the substrate 210. The doped region 224′ may be doped by an implantation technique. In some embodiments, the doped region 224′ may include nitrogen. In some embodiments, the ion implantation energy of the doped region 224′ may range from about 10 keV to about 30 keV, such as 10 keV, 15 keV, 20 keV, 25 keV, or 30 keV.

Referring to FIG. 7C, a doped region 222′ may be doped into the substrate 210. The doped region 222′ may be doped by an implantation technique. In some embodiments, the doped region 222′ may include phosphorous, arsenic, antimony, or a combination thereof. In some embodiments, the implantation energy of the doped region 222′ may be greater than that of the doped region 224′. In some embodiments, implantation energy of the doped region 222′ may range from about 20 keV to about 40 keV, such as 20 keV, 25 keV, 30 keV, 35 keV, or 40 keV. Although FIG. 7C illustrates that the doped region 224′ may be formed before the doped region 222′, the doped region 222′ may be formed before the doped region 224′ in other embodiments.

Referring to FIG. 7D, a fuse medium 231 may be formed over the surface 210s1 of the substrate 210. In some embodiments, the doped region 222′ may be activated to form a fuse doped region 222. In some embodiments, the doped region 224′ may be activated to form a resistance modification doped region 224. In some embodiments, a fuse medium 231 may be formed by a thermal oxidation, and therefore the doped region 222′ and the doped region 224′ may be activated.

Referring to FIG. 7E, the fuse medium 231 may be patterned. A gate electrode 232 may be formed over the fuse medium 231. Spacers 241 and 242 may be on opposite sides of the gate electrode 232. An S/D region 223 may be formed between the fuse doped region 222 and the isolation region 212. The gate electrode 232, spacer 241, and/or spacer 242 may be formed by a deposition process, such as a chemical vapor deposition (CVD) process, an atomic layer deposition (ALD) process, a physical vapor deposition (PVD) process, or a combination thereof. The S/D region 223 may be formed by an implantation technique.

Referring to FIG. 7F, a conductive contact 251 may be formed over the gate electrode 232. A conductive contact 252 may be formed over the S/D region 223. A metal layer 261 may be formed over the conductive contact 251. A metal layer 262 may be formed over the conductive contact 252. The conductive contact 251, conductive contact 252, metal layer 261, and metal layer 262 may be formed by a deposition process, such as a CVD process, an ALD process, a PVD process, a sputtering process, a plating process, or a combination thereof. It should be noted that some processes or stages are omitted for brevity. For example, an interlayer dielectric (ILD) may be formed over the substrate 210 before the conductive contact 251 and conductive contact 252 are formed.

FIG. 8 illustrates a diagram showing a relation between a temperature and a resistance of a hopping type fuse. The horizontal axis indicates a resistance. The vertical axis indicates a cumulative percentage of test results of comparative semiconductor devices. The solid line is a distribution of resistances of semiconductor devices under a higher temperature. The dotted line is a distribution of resistances of semiconductor devices under a lower temperature. The resistance is measured after a fuse medium is blown out under an operation current ranging from about 0.4 mA to about 1.2 mA. The operation voltage may range from about 4V to about 6V. The comparative semiconductor devices do not include a resistance modification doped region, such as the resistance modification doped region 224 as shown in FIG. 2. As shown in FIG. 8, the comparative semiconductor device has a lower resistance under a higher temperature and a higher resistance under a lower temperature. As shown in FIG. 8, the resistance of 90% of the measurement results range between about 3 kohm and about 15 kohm.

FIG. 9 illustrates a diagram showing a relation between a temperature and a resistance of an ohmic type fuse. The horizontal axis indicates a resistance. The vertical axis indicates a cumulative percentage of test results of comparative semiconductor devices. The solid line is a distribution of resistances of semiconductor devices under a higher temperature. The dotted line is a distribution of resistances of semiconductor devices under a lower temperature. The resistance is measured after a fuse medium is blown out under an operation current ranging from about 0.4 mA to about 1.2 mA. The operation voltage may range from about 4V to about 6V. The comparative semiconductor devices include a resistance modification doped region, such as the resistance modification doped region 224 as shown in FIG. 2. The dopant concentration of the resistance modification doped region 224 is about 3E15. As shown in FIG. 9, the semiconductor device has a lower resistance under a lower temperature and a higher resistance under a higher temperature. As shown in FIG. 9, the resistance of 90% of the measurement results range between about 1 kohm and about 4 kohm. Therefore, in comparison with FIG. 8, the deviation of the resistance of FIG. 9 is smaller.

FIG. 10 illustrates a diagram showing a relation between a temperature and a resistance of an ohmic type fuse. The horizontal axis indicates a resistance. The vertical axis indicates a cumulative percentage of test results of comparative semiconductor devices. The solid line is a distribution of resistances of semiconductor devices under a higher temperature. The dotted line is a distribution of resistances of semiconductor devices under a lower temperature. The resistance is measured after a fuse medium is blown out under an operation current ranging from about 0.4 mA to about 1.2 mA. The operation voltage may range from about 4V to about 6V. The comparative semiconductor devices include a resistance modification doped region, such as the resistance modification doped region 224 as shown in FIG. 2. The dopant concentration of the resistance modification doped region 224 is about 5E15. As shown in FIG. 10, the semiconductor device has a lower resistance under a lower temperature and a higher resistance under a higher temperature. As shown in FIG. 10, the resistance of 90% of the measurement results range between about 1 kohm and about 3.7 kohm. Therefore, in comparison with FIG. 8, the deviation of the resistance of FIG. 10 is smaller.

FIG. 11 is a flowchart illustrating a method 300 of manufacturing a semiconductor device, in accordance with some embodiments of the present disclosure.

The method 300 may begin with operation 310 in which a substrate is provided. The substrate may include a well region with a first conductive type.

The method 300 may begin with operation 320 in which a fuse doped region is formed within the substrate. The fuse doped region may have a second conductive type different from the first conductive type.

The method 300 may begin with operation 330 in which a resistance modification doped region is formed within the substrate. The resistance modification doped region may have a second conductive type different from the first conductive type. The resistance modification doped region may partially overlap the fuse doped region.

The method 300 may begin with operation 340 in which the resistance modification doped region and the fuse doped region are activated. A fuse medium may be formed over the fuse doped region and over the resistance modification doped region.

The method 300 may begin with operation 350 in which a gate electrode is formed over the fuse medium to cover the fuse doped region and the resistance modification doped region. An S/D region is formed adjacent to the fuse doped region and within the substrate.

The method 300 may begin with operation 360 in which conductive contacts and metal layers may be formed. As a result, a semiconductor device may be produced.

The method 300 is merely an example, and is not intended to limit the present disclosure beyond what is explicitly recited in the claims. Additional operations can be provided before, during, or after each operations of the method 300, and some operations described can be replaced, eliminated, or reordered for additional embodiments of the method. In some embodiments, the method 300 can include further operations not depicted in FIG. 11. In some embodiments, the method 300 can include one or more operations depicted in FIG. 11.

One aspect of the present disclosure provides a semiconductor device. The semiconductor device includes a substrate, a well region, a fuse medium, a gate electrode, a fuse doped region, a source/drain (S/D) region, and a resistance modification doped region. The well region is within the substrate with a first conductive type. The fuse medium is disposed over the substrate. The gate electrode is disposed over the fuse medium. The fuse doped region is under the gate electrode with a second conductive type different from first conductive type. The S/D region is adjacent to the fuse doped region with the second conductive type. The resistance modification doped region has the second conductive type and partially overlaps the fuse doped region.

One aspect of the present disclosure provides a semiconductor a fuse medium, a gate electrode, a fuse doped region, a source/drain (S/D) region, and nitrogen derivative impurities. The well region is within the substrate with a first conductive type. The fuse medium is disposed over the substrate. The gate electrode is disposed over the fuse medium. The fuse doped region is under the gate electrode with a second conductive type different from first conductive type. The S/D region is adjacent to the fuse doped region with the second conductive type. The nitrogen derivative impurities are within the substrate and under the gate electrode.

Another aspect of the present disclosure provides a method of manufacturing a semiconductor device. The method includes: providing a substrate, wherein a well region is within the substrate with a first conductive type; forming a resistance modification doped region within the substrate, wherein the resistance modification doped region has a second conductive type different from the first conductive type; forming a fuse doped region within the substrate, wherein the fuse doped region has the second conductive type; and forming a gate electrode over the fuse doped region.

The embodiments of the present disclosure provide a semiconductor device. The semiconductor device may include a resistance modification doped region. The resistance modification doped region may make a fuse to be an ohmic type fuse when a fuse medium is blown out under an operation current under 4 mA (e.g., a current under 1.2 mA). The resistance of an ohmic type fuse is positively proportional to a temperature and has a resistance with a lower deviation. As a result, the misjudgment of the determination of a read operation and/or a write operation can be reduced.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a well region within the substrate with a first conductive type;
a fuse medium disposed over the substrate;
a gate electrode disposed over the fuse medium;
a fuse doped region under the gate electrode with a second conductive type different from first conductive type;
a source/drain (S/D) region adjacent to the fuse doped region with the second conductive type; and
nitrogen derivative impurities within the substrate and under the gate electrode.

2. The semiconductor device of claim 1, wherein the nitrogen derivative impurities comprise nitride.

3. The semiconductor device of claim 1, wherein the nitrogen derivative impurities comprise oxynitride.

4. The semiconductor device of claim 1, wherein the nitrogen derivative impurities are located within the fuse doped region.

5. The semiconductor device of claim 1, wherein the nitrogen derivative impurities are located within the S/D region.

6. The semiconductor device of claim 1, wherein the nitrogen derivative impurities are located outside the fuse doped region.

7. The semiconductor device of claim 1, wherein the fuse medium is configured to be blown under a current ranging from about 0.4 mA to about 1.2 mA.

8. The semiconductor device of claim 7, wherein a resistance of the fuse medium is positively proportional to a temperature.

9. The semiconductor device of claim 1, wherein the fuse doped region is in contact with the S/D region.

10. The semiconductor device of claim 1, wherein a concentration of the nitrogen derivative impurities is gradient.

11. The semiconductor device of claim 1, further comprises:
nitrogen atoms located within the fuse doped region.

12. The semiconductor device of claim 11, wherein the nitrogen atoms are located within the S/D region.

13. A method of manufacturing a semiconductor device, comprising:
providing a substrate, wherein a well region is within the substrate with a first conductive type;
forming a resistance modification doped region within the substrate, wherein the resistance modification doped region has a second conductive type different from the first conductive type;
forming a fuse doped region within the substrate, wherein the fuse doped region has the second conductive type; and
forming a gate electrode over the fuse doped region.

14. The method of claim 13, further comprising:
forming a fuse medium after forming the resistance modification doped region.

15. The method of claim 13, wherein the resistance modification doped region comprises nitrogen.

16. The method of claim 13, wherein the resistance modification doped region is formed by an implantation energy ranging from about 10 keV to about 30 keV.
